(19) United States
(12) Patent Application Publication
(10) Pub. No.: US 2021/0071518 A1
(43) Pub. Date: Mar. 11, 2021

(54) Method for interpreting and evaluating production profile of multi-layer gas reservoir based on downhole distributed temperature monitoring

(71) Applicant: SOUTHWEST PETROLEUM UNIVERSITY, CHENGDU CITY (CN)

(72) Inventors: Mingqiang Wei, CHENGDU CITY (CN); Yonggang Duan, CHENGDU CITY (CN); Hao Liang, CHENGDU CITY (CN); Muwang Wu, CHENGDU CITY (CN); Ruiduo Zhang, CHENGDU CITY (CN); Zijian Wu, CHENGDU CITY (CN); Shihao Wei, CHENGDU CITY (CN); Shuyao Sheng, CHENGDU CITY (CN); Tao Yue, CHENGDU CITY (CN); Xu Chen, CHENGDU CITY (CN); Yihe Du, CHENGDU CITY (CN); Tengyi Long, CHENGDU CITY (CN)

(73) Assignee: SOUTHWEST PETROLEUM UNIVERSITY, CHENGDU CITY (CN)

(21) Appl. No.: 17/084,693

(22) Filed: Oct. 30, 2020

(30) Foreign Application Priority Data
Jul. 20, 2020 (CN) 202010698375.5

(51) Int. Cl. E21B 47/103

(52) U.S. Cl. CPC E21B 47/103

(57) ABSTRACT

The present invention discloses a method for interpreting and evaluating production profile of multi-layer gas reservoir based on downhole distributed temperature monitoring, including: obtaining downhole distributed temperature monitoring data of target well; preprocessing the downhole distributed temperature monitoring data; segmenting the temperature monitoring data according to test curve characteristics of the target well and logging interpretation results; using a multi-layer gas reservoir seepage pressure field—temperature field coupled model to calculate temperatures of each layer in the borehole production profile of the target well by numerical simulation method; comparing the temperatures of each layer of the borehole production profile with the temperature monitoring data after segmentation, obtaining the optimal flow rate of each production layer with optimization theories, and obtaining the production profile of the target well based on the optimal flow rate of each production layer.

### TECHNICAL FIELD

The present invention relates to a method for interpreting and evaluating production profile of multi-layer gas reservoir based on downhole distributed temperature monitoring, belonging to the technical field of oil and gas exploitation.

### DESCRIPTION OF PRIOR ART

How to obtain the production profile of oil and gas wells in a real-time, efficient and accurate manner has always been a bottleneck problem that is of great concern to petroleum engineering technicians. Although the production profile testing technology based on production logging can determine the production of downhole fluids, it still has many deficiencies, such as long monitoring time, poor continuity of timeliness, instrument removal affecting the smooth operation of oil and gas well, large size and poor well type adaptability of monitoring instrument, large error in monitoring results, high cost, etc. In recent years, exploratory wells in Tarim Basin and Yinggehai Basin in China have showed the characteristics of ultra-high temperature and high pressure. Traditional production profile monitoring tools cannot meet the production profile testing requirements under extreme conditions, which has seriously affected the accurate understanding of reservoir productivity in the exploration area. At present, there is no method for interpreting and evaluating production profile of multi-layer gas well with high temperature and high pressure based on downhole distributed optical fiber temperature monitoring.

### SUMMARY OF THE INVENTION

The present invention mainly overcomes the shortcomings in the prior art and proposes a method for interpreting and evaluating production profile of multi-layer gas reservoir based on downhole distributed temperature monitoring. The present invention can accurately obtain the production profile of oil and gas wells.

The technical solution provided by the present invention to the above technical problem is a method for interpreting and evaluating production profile of multi-layer gas reservoir based on downhole distributed temperature monitoring, including the following steps:

Step S1: obtaining a downhole distributed temperature monitoring data of a target well;

Step S2: preprocessing the downhole distributed temperature monitoring data to obtain a temperature monitoring data of normal trend at different times;

Step S3: segmenting the temperature monitoring data obtained in Step S2 according to a test curve characteristics of the target well and logging interpretation results;

Step S4: using a multi-layer gas reservoir seepage pressure field—temperature field coupled model to calculate temperatures of each layer in the borehole production profile of the target well by a numerical simulation method; and

Step S5: comparing the temperatures calculated in Step S4 of each layer of the borehole production profile with the temperature monitoring data after segmentation in Step S3, obtaining an optimal flow rate of each production layer with optimization theories, and obtaining the production profile of the target well based on the optimal flow rate of each production layer.

The further technical solution is that Step S2 includes:

comparing and analyzing the downhole distributed temperature monitoring data by global probability method, preprocessing the temperature monitoring data by smoothing filtering, and obtaining temperature monitoring data of the normal trend at different times.

The further technical solution is that the multi-layer gas reservoir seepage pressure field—temperature field coupled model in Step S4 includes a multi-layer gas reservoir pressure field model and a multi-layer gas reservoir downhole temperature field model.

The multi-layer gas reservoir pressure field model is as follows:

$$\frac{1}{r} \frac{\partial }{\partial r} ( r \frac{\partial {p}_{Li}}{\partial r} ) = \frac{{φ}_{Li} {μ}_{Li} {c}_{tLi}}{{k}_{Li}} \frac{\partial {p}_{Li}}{\partial t} i = 1 , 2 , 3 ⋯ n .$$

Inner boundary condition:

$$\frac{2 π kh}{μ} {( r \frac{\partial {p}_{Li}}{\partial r} )}_{r = {r}_{w}} = {q}_{Li} i = 1 , 2 , 3 ⋯ n .$$

Closed outer boundary:

$${( \frac{\partial p}{\partial r} )}_{r = {r}_{e}} = 0 ( t \geq 0 ) .$$

Where, r is a distance from the well, in; p_{Li} is a pressure of Layer i, and i is serial number of gas reservoir layer; ϕ_{Li} is a porosity of Layer i, decimal; c_{tLi} is a comprehensive compressibility of Layer i, MPa⁻¹; k_{Li} is a permeability of Layer i, mD; r_{w} is a well radius, in; rₑ is a well control radius, in; q_{Li} is a gas yield of Layer i, m³/d; t is the production time, day.

The downhole temperature field model of multi-layer gas reservoir is as follows:

$$\frac{\partial }{\partial } {ρ}_{Li} {U}_{Li} = - ∇ . ( {ρ}_{Li} {U}_{Li} {v}_{Li} ) - ( τ \text{:} ∇ {v}_{Li} ) - ∇ . {q}_{Li} ;$$

where, U_{Li} is an internal energy per unit mass of Layer i, J/Kg; ρ_{Li} is a fluid density of Layer i, kg/m³; v_{Li} is a speed in Layer i, m/s; τ is a viscous dissipation coefficient; q_{Li} is a gas yield of Layer i, m³/d.

The further technical solution is that Step S5 includes:

comparing the temperature of each layer of the production profile with the temperature data after segmentation, then adjusting the permeability and the flow rate of each production layer if the error between them is greater than 5%;

recalculating the temperature of each layer of the borehole production profile, and then re-comparing, until the error is not greater than 5% and the flow rate in each production layer after adjustment is the optimal flow rate; and

working out the production profile of the target well according to the optimal flow rate of each production layer.

The present invention has the following beneficial effects: based on the gas state equation and mass conservation and energy laws, the present invention proposes a method for evaluating production profile by the coupling of seepage pressure field and temperature field of gas reservoir, which can accurately obtain gas well production profile, with great practical significance for accurately evaluating the productivity of multi-layer gas reservoirs with high temperature and high pressure in China and improving the benefits of exploration and development.

### BRIEF DESCRIPTION OF THE DRAWINGS

FIG. 1 is a schematic diagram of multi-layer gas reservoir;

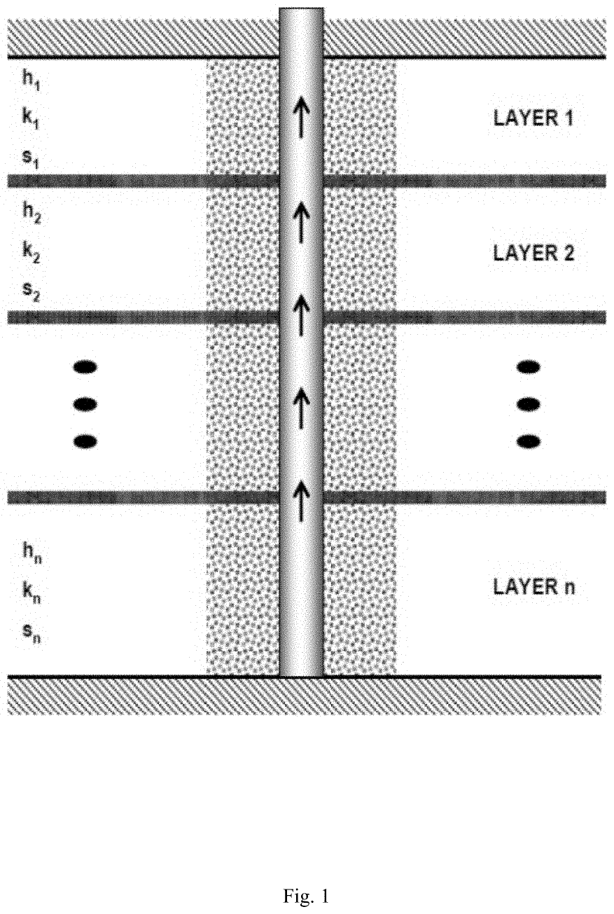

FIG. 2 is a comparison diagram of processed and unprocessed results of temperature tests at different times;

FIG. 3 is a segmentation diagram of distributed temperature monitoring and interpretation;

FIG. 4 is a diagram of temperature prediction of multi-layer production profile at different times;

FIG. 5 is a comparison diagram of temperature and test data; and

FIG. 6 is a diagram of a production profile.

### DETAILED DESCRIPTION OF THE PREFERRED EMBODIMENTS

The present invention will be further described with the following embodiments and figures.

This embodiment provides a method for interpreting and evaluating production profile of multi-layer gas reservoir based on downhole distributed temperature monitoring, comprising the following steps:

Step S1: obtaining the downhole distributed temperature monitoring data of the target well.

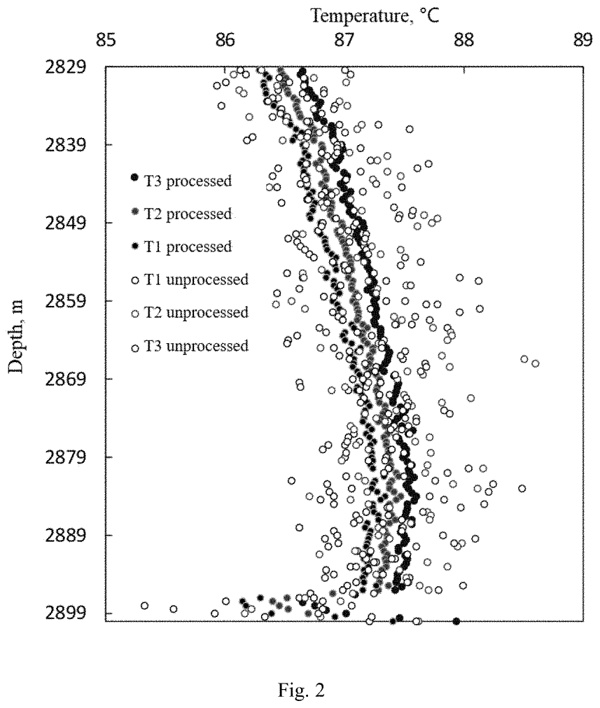

Step S2: comparing and analyzing the downhole distributed temperature monitoring data by the global probability method, and then preprocessing the temperature monitoring data by smoothing filtering to obtain the temperature monitoring data of the normal trend at different times. The preprocessed temperature monitoring data is shown in FIG. 2.

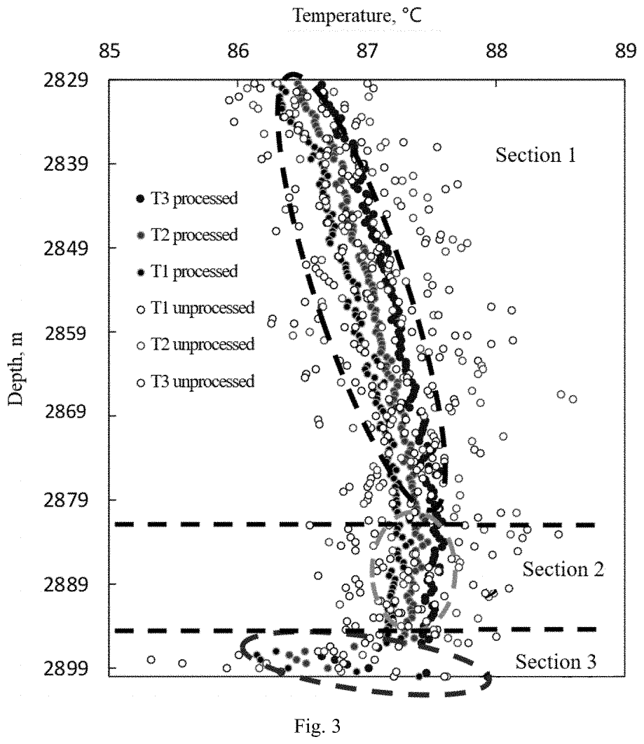

Step S3: segmenting the temperature monitoring data obtained in Step S2 according to the test curve characteristics of the target well and the logging interpretation results, as shown in FIG. 3.

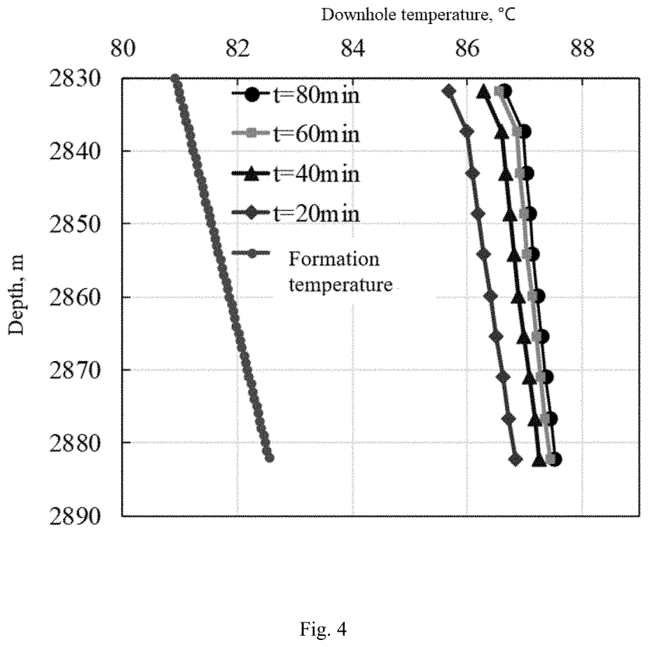

Step S4: using a multi-layer gas reservoir seepage pressure field—temperature field coupled model to calculate the temperature of each layer in the borehole production profile of the target well by a numerical simulation method, as shown in FIG. 4.

The multi-layer gas reservoir seepage pressure field—temperature field coupled model in Step S4 includes a multi-layer gas reservoir pressure field model and a multi-layer gas reservoir downhole temperature field model.

The multi-layer gas reservoir pressure field model is as follows:

$$\frac{1}{r} \frac{\partial }{\partial r} ( r \frac{\partial {p}_{Li}}{\partial r} ) = \frac{{φ}_{Li} {μ}_{Li} {c}_{tLi}}{{k}_{Li}} \frac{\partial {p}_{Li}}{\partial t} i = 1 , 2 , 3 ⋯ n .$$

Inner boundary condition:

$$\frac{2 π kh}{μ} {( r \frac{\partial {p}_{Li}}{\partial r} )}_{r = {r}_{w}} = {q}_{Li} i = 1 , 2 , 3 ⋯ n .$$

Closed outer boundary:

$${( \frac{\partial p}{\partial r} )}_{r = {r}_{e}} = 0 ( t \geq 0 ) .$$

Where, r is a distance from the well, in; p_{Li} is a pressure of Layer i, and i is serial number of gas reservoir layer; ϕ_{Li} is a porosity of Layer i, decimal; c_{tLi} is a comprehensive compressibility of Layer i, MPa⁻¹; k_{Li} is a permeability of Layer i, mD; r_{w} is a well radius, in; rₑ is a well control radius, in; q_{Li} is a gas yield of Layer i, m³/d; t is the production time, day.

The downhole temperature field model of multi-layer gas reservoir is as follows:

$$\frac{\partial }{\partial } {ρ}_{Li} {U}_{Li} = - ∇ . ( {ρ}_{Li} {U}_{Li} {v}_{Li} ) - ( τ \text{:} ∇ {v}_{Li} ) - ∇ . {q}_{Li} ;$$

where, U_{Li} is an internal energy per unit mass of Layer i, J/Kg; ρ_{Li} is a fluid density of Layer i, kg/m³; v_{Li} is a speed in Layer i, m/s; τ is a viscous dissipation coefficient; q_{Li} is a gas yield of Layer i, m³/d.

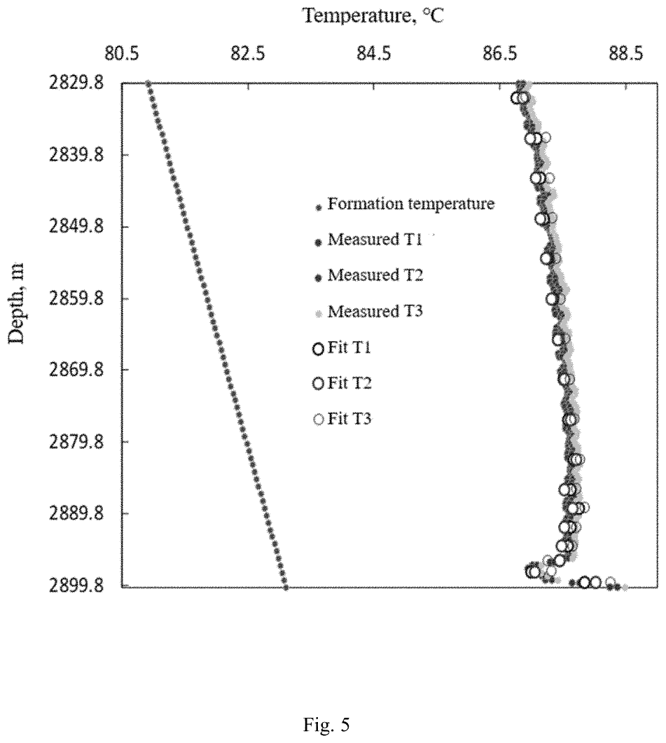

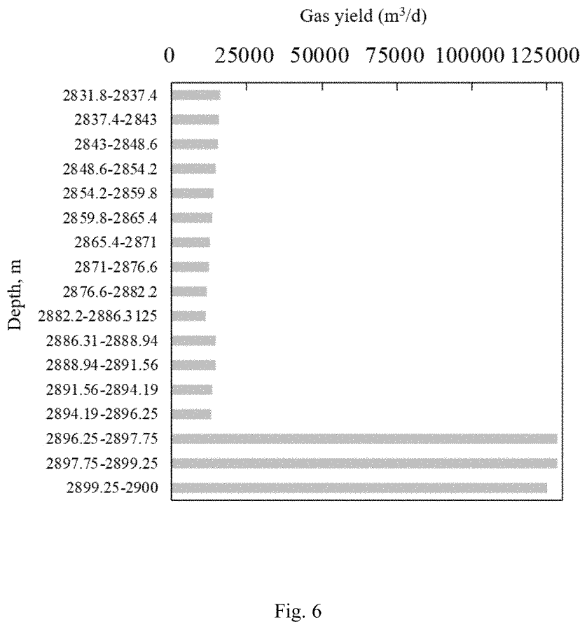

Step S5: comparing the temperature calculated in Step S4 of each layer of the borehole production profile with the temperature monitoring data after segmentation in Step S3, as shown in FIG. 5, then adjusting the permeability and the flow rate of each production layer if the error between them is greater than 5%; recalculating the temperature of each layer of the borehole production profile, and then re-comparing, until the error is not greater than 5% and the flow rate in each production layer after adjustment is the optimal flow rate; and working out the production profile of the target well according to the optimal flow rate of each production layer (as shown in FIG. 6).

The present invention can accurately obtain the production profile of oil and gas wells, with great practical significance for accurately evaluating the productivity of multi-layer gas reservoirs with high temperature and pressure in China and improving the benefits of exploration and development.

The above are not intended to limit the present invention in any form. Although the present invention has been disclosed as above with embodiments, it is not intended to limit the present invention. Those skilled in the art, within the scope of the technical solution of the present invention, can use the disclosed technical content to make a few changes or modify the equivalent embodiment with equivalent changes. Within the scope of the technical solution of the present invention, any simple modification, equivalent change and modification made to the above embodiments according to the technical essence of the present invention are still regarded as a part of the technical solution of the present invention.

What is claimed is:

1. A method for interpreting and evaluating production profile of multi-layer gas reservoir based on downhole distributed temperature monitoring, comprising the following steps:
Step S1: obtaining a downhole distributed temperature monitoring data of a target well;
Step S2: preprocessing the downhole distributed temperature monitoring data to obtain a temperature monitoring data of normal trend at different times;
Step S3: segmenting the temperature monitoring data obtained in Step S2 according to a test curve characteristics of the target well and logging interpretation results;
Step S4: using a multi-layer gas reservoir seepage pressure field—temperature field coupled model to calculate temperatures of each layer in the borehole production profile of the target well by a numerical simulation method; and
Step S5: comparing the temperatures calculated in Step S4 of each layer of the borehole production profile with the temperature monitoring data after segmentation in Step S3, obtaining an optimal flow rate of each production layer with optimization theories, and obtaining the production profile of the target well based on the optimal flow rate of each production layer.

2. The method for interpreting and evaluating production profile of multi-layer gas reservoir based on downhole distributed temperature monitoring according to claim 1, wherein Step S2 comprises:
comparing and analyzing the downhole distributed temperature monitoring data by a global probability method, preprocessing the temperature monitoring data by smoothing filtering, and obtaining the temperature monitoring data of the normal trend at different times.

3. The method for interpreting and evaluating production profile of multi-layer gas reservoir based on downhole distributed temperature monitoring according to claim 1, wherein the multi-layer gas reservoir seepage pressure field—temperature field coupled model in Step S4 comprises a multi-layer gas reservoir pressure field model and a multi-layer gas reservoir downhole temperature field model;
the multi-layer gas reservoir pressure field model is as follows:
$$\frac{1}{r} \frac{\partial }{\partial r} ( r \frac{\partial {p}_{Li}}{\partial r} ) = \frac{{φ}_{Li} {μ}_{Li} {c}_{tLi}}{{k}_{Li}} \frac{\partial {p}_{Li}}{\partial t} i = 1 , 2 , 3 ⋯ n ;$$
inner boundary condition:
$$\frac{2 π kh}{μ} {( r \frac{\partial {p}_{Li}}{\partial r} )}_{r = {r}_{w}} = {q}_{Li} i = 1 , 2 , 3 ⋯ n ;$$
closed outer boundary:
$${( \frac{\partial p}{\partial r} )}_{r = {r}_{e}} = 0 ( t \geq 0 ) ;$$
where, r is a distance from the well, in; p_{Li} is a pressure of Layer i, and i is serial number of gas reservoir layer; ϕ_{Li} is a porosity of Layer i, decimal; c_{tLi} is a comprehensive compressibility of Layer i, MPa⁻¹; k_{Li} is a permeability of Layer i, mD; r_{w} is a well radius, in; rₑ is a well control radius, in; q_{Li} is a gas yield of Layer m³/d; t is the production time, day;
the downhole temperature field model of multi-layer gas reservoir is as follows:
$$\frac{\partial }{\partial } {ρ}_{Li} {U}_{Li} = - ∇ . ( {ρ}_{Li} {U}_{Li} {v}_{Li} ) - ( τ \text{:} ∇ {v}_{Li} ) - ∇ . {q}_{Li} ;$$
where, U_{Li} is an internal energy per unit mass of Layer i, J/Kg; ρ_{Li} is a fluid density of Layer i, kg/m³; v_{Li} is a speed in Layer i, m/s; τ is a viscous dissipation coefficient; q_{Li} is a gas yield of Layer i, m³/d.

4. The method for interpretation and evaluation of downhole distributed temperature monitoring and production profile of multi-layer gas reservoir according to claim 3, wherein Step S5 comprises:
comparing the temperature of each layer of the production profile with the temperature data after segmentation, then adjusting the permeability and the flow rate of each production layer if an error between them is greater than 5%;
recalculating the temperature of each layer of the borehole production profile, and then re-comparing, until the error is not greater than 5% and the flow rate in each production layer after adjustment is the optimal flow rate; and
working out the production profile of the target well according to the optimal flow rate of each production layer.
